(19) United States
(12) Patent Application Publication
(10) Pub. No.: US 2006/0169974 A1
(43) Pub. Date: Aug. 3, 2006

(54) Thin film transistor, a method of manufacturing the same, and a flat panel display device including the thin film transistor

(76) Inventors: Taek Ahn, Suwon-si (KR); Jae-Bon Koo, Suwon-si (KR); Min-Chul Suh, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/338,089

(22) Filed: Jan. 24, 2006

(30) Foreign Application Priority Data
Jan. 28, 2005 (KR) 10-2005-0007995

(51) Int. Cl. H01L 29/08

(52) U.S. Cl. 257/40

(57) ABSTRACT

Provided are a thin film transistor, a method of manufacturing the same, and a flat panel display device including the thin film transistor. The thin film transistor includes: a gate electrode; source and drain electrodes insulated from the gate electrode; an organic semiconductor layer that is insulated from the gate electrode and electrically connected to the source and drain electrodes; an insulating layer that insulates the gate electrode from the source and drain electrodes or the organic semiconductor layer; and a channel formation-promoting layer that contacts an opposite region of a channel region of the organic semiconductor layer, and contains a compound having a functional group, which fixes electric charges moving toward the opposite region of the channel region to the opposite region of the channel region. Thus, the thin film transistor has a low threshold voltage and excellent electric charge mobility.

### CROSS-REFERENCE TO RELATED APPLICATIONS

This application claims the benefit of Korean Patent Application No. 10-2005-0007995, filed on Jan. 28, 2005, in the Korean Intellectual Property Office, the disclosure of which is incorporated herein in its entirety by reference.

### BACKGROUND OF THE INVENTION

1. Field of the Invention

The present embodiments relate to a thin film transistor, a method of manufacturing the same, a flat panel display device including the thin film transistor, and more particularly, to a thin film transistor which includes a channel formation-promoting layer in order to have a low threshold voltage and increased electric charge mobility, a method of manufacturing the same, and a flat panel display device including the thin film transistor.

2. Description of the Related Art

Thin film transistors (TFTs), which are used in flat panel display devices, such as liquid crystalline display devices, organic light emitting display devices, inorganic light emitting display devices, and the like, are used as switching devices for controlling pixel operations and as driving devices for operating pixels.

A TFT includes a semiconductor layer which includes source and drain regions and a channel region interposed between the source region and the drain region, a gate electrode which is insulated from the semiconductor layer and located corresponding to the channel region, and source and drain electrodes respectively contacting the source and drain regions.

In general, the source and drain electrodes are made of a small work function metal to smooth the flow of electric charges. However, due to high contact resistance of a contact region between such metal and the semiconductor layer, the properties of the device deteriorate, and further consumption power increases.

Recently, studies on organic thin film transistors have been carried out. Organic thin film transistors include organic semiconductor layers which can be manufactured at low temperatures so that plastic substrates can be used. Organic thin film transistors are disclosed in, for example, Korean Patent Publication No. 2004-0012212.

However, the threshold voltage and electric charge mobility of conventional thin film transistors are far behind desired levels. Thus, the threshold voltage and electric charge mobility needs to be improved.

### SUMMARY OF THE INVENTION

The present embodiments provide a thin film transistor, which includes a channel formation-promoting layer in order to have a low threshold voltage and an excellent electric charge mobility, a method of manufacturing the thin film transistor, and a flat panel display device including the thin film transistor.

According to an aspect of the present embodiments, there is provided a thin film transistor including: a gate electrode; source and drain electrodes insulated from the gate electrode; an organic semiconductor layer that is insulated from the gate electrode and electrically connected to the source and drain electrodes; an insulating layer that insulates the gate electrode from the source and drain electrodes or the organic semiconductor layer; and a channel formation-promoting layer that contacts an opposite region of a channel region of the organic semiconductor layer, and contains a compound having a functional group, which fixes electric charges moving toward the opposite region of the channel region to the opposite region of the channel region.

According to another aspect of the present embodiments, there is provided a method of manufacturing a thin film transistor, the method including: forming an insulating layer to cover a gate electrode, which is formed on an insulating substrate; forming source and drain electrodes in predetermined positions corresponding both ends of the gate electrode on the insulating layer; forming an organic semiconductor layer on the source and drain electrodes; and forming a channel formation-promoting layer contacting an opposite region of a channel region of the organic semiconductor layer.

According to yet another aspect of the present embodiments, there is provided a method of manufacturing a thin film transistor, the method including: forming an insulating layer to cover a gate electrode formed on an insulating substrate; forming an organic semiconductor layer on the insulating layer; forming source and drain electrodes in predetermined positions corresponding the gate electrode on the organic semiconductor layer; and forming a channel formation-promoting layer contacting an opposite region of a channel region of the organic semiconductor layer.

According to still another aspect of the present embodiments, there is provided a method of manufacturing a thin film transistor, the method comprising: forming source and drain electrodes on a substrate; forming a channel formation-promoting layer on the source and drain electrodes formed on the substrate; forming an organic semiconductor layer on the channel formation-promoting layer; forming an insulating layer covering the organic semiconductor layer; and forming a gate electrode in a predetermined position corresponding to the source and drain electrodes on the insulating layer.

According to a further aspect of the present embodiments, there is provided a method of manufacturing a thin film transistor, the method comprising: forming a channel formation-promoting layer on a substrate; forming source and drain electrodes on the channel formation-promoting layer; forming an organic semiconductor layer on the source and drain electrodes; and forming an insulating layer covering the organic semiconductor layer; and forming a gate electrode in a predetermined position corresponding to the source and drain electrodes on the insulating layer.

According to further aspect of the present embodiments, there is provided a flat panel display device including the thin film transistor in each pixel, wherein the source electrode on the drain electrode of the thin film transistor is connected to a pixel electrode.

### BRIEF DESCRIPTION OF THE DRAWINGS

The above and other features and advantages of the present embodiments will become more apparent by describing in detail exemplary embodiments thereof with reference to the attached drawings in which:

FIGS. 1 and 2 are sectional views illustrating a mechanism for promoting the formation off a channel by a channel formation-promoting layer of a thin film transistor (TFT) according to an embodiment;

FIGS. 3 through 6 are TFTs according to various embodiments; and

FIG. 7 is a flat panel display device including a TFT according to an embodiment.

### DETAILED DESCRIPTION OF THE INVENTION

Hereinafter, the present embodiments will be described in detail with reference to drawings.

A thin film transistor (TFT) according to an embodiment includes a channel formation-promoting layer. The channel formation-promoting layer contacts an opposite region of a channel region of an organic semiconductor layer, and is made of a compound having a functional group, which can fix electric charges moving toward the opposite region of the channel region to the opposite region of the channel region. In detail, the channel formation-promoting layer is made of a compound having an electron-acceptor group or an electron-donor group, which can withdraw electric charges (electrons or holes) moving toward the opposite region of the channel region, to the interface between the organic semiconductor layer and the channel formation-promoting layer.

In these embodiments, the term “channel” means a kind of path that is formed in an organic semiconductor layer when an electrical signal is applied to the gate electrode. The “channel” allows electrical communication between a source electrode and a drain electrode. In these embodiments, the term “channel region” means a region that is formed when an electrical signal is applied to a gate electrode.

Due to the channel formation-promoting layer, the channel region can be more easily formed in the organic semiconductor layer when a gate electrode of the TFT is supplied with a voltage. Therefore, the TFT has a low threshold voltage and high electric charge mobility.

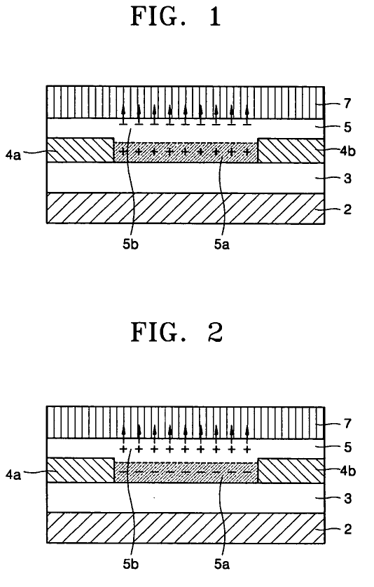

A mechanism for the easy formation of the channel by the channel formation-promoting layer is illustrated in FIG. 1 and FIG. 2.

FIG. 1 schematically illustrates the formation of a channel region 5a by movement of electric charges of a P-type organic semiconductor layer 5 in a TFT including the P-type organic semiconductor layer 5 and a channel formation-promoting layer 7 when a gate electrode 2 is supplied with a voltage.

Referring to FIG. 1, the TFT includes the gate electrode 2, an insulating layer 3 insulating the gate electrode 2 from the organic semiconductor layer 5, source and drain electrodes 4a and 4b, the organic semiconductor layer 5, and the channel formation-promoting layer 7, which are sequentially formed. When the gate electrode 2 is supplied with a (−) voltage, holes (+) of the organic semiconductor layer 5 move toward the gate electrode 2 to form the channel region 5a and electrons (−) move toward an opposite region 5b of the channel region 5a. Electrons of the opposite region 5b of the channel region 5a are strongly withdrawn to the interface between the organic semiconductor layer 5 and the channel formation-promoting layer 7 by the channel formation-promoting layer 7, which contacts the opposite region 5b of the channel region 5a and is made of a compound having an electron-acceptor group. As a result, the formation of the channel region 5a can be promoted.

FIG. 2 schematically illustrates the formation of a channel region 5a by a movement of electric charges of an N-type organic semiconductor layer 5 in a TFT including the N-type organic semiconductor layer 5 and a channel formation-promoting layer 7 when a gate electrode 2 is supplied with a voltage.

The TFT illustrated in FIG. 2, having the same structure as the TFT of FIG. 1, includes a gate electrode 2, an insulating layer 3 insulating the gate electrode 2 from the organic semiconductor layer 5, source and drain electrodes 4a and 4b, the organic semiconductor layer 5, and the channel formation-promoting layer 7, which are sequentially formed. When the gate electrode 2 is supplied with a (+) voltage, electrons of the organic semiconductor layer 5 move toward the gate electrode 2 to form a channel region 5a and holes move toward an opposite region 5b of the channel region 5a. Holes of the opposite region 5b of the channel region 5a are strongly withdrawn to the interface between the organic semiconductor layer 5 and the channel formation-promoting layer 7 by the channel formation-promoting layer 7, which contacts the opposite region 5b of the channel region 5a and is made of a compound having an electron-donor group. As a result, the formation of the channel region 5a can be promoted.

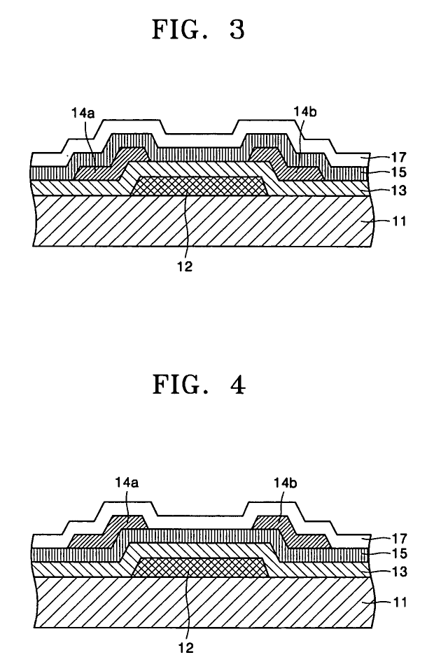

Hereinafter, TFTs according to some embodiments will be described in detail with reference to FIGS. 3 through 6.

FIG. 3 is a sectional view of a TFT according to an embodiment.

Referring to FIG. 3, a substrate 11 may be any substrate that is commonly used in an organic light emitting device. The substrate 11 may be a glass substrate and a transparent plastic substrate selected in consideration of transparency, surface smoothness, ease of use, waterproof, etc. A gate electrode 12 with a predetermined pattern is formed on the substrate 11. The gate electrode 12 may be made of Au, Ag, Cu, Ni, Pt, Pd, Al, Mo, an alloy of Al and Nd, an alloy of Mo and W, or the like. However, the material for the gate electrode 12 is not limited thereto. An insulating layer 13 covers the gate electrode 12. The insulating layer 13 is made of an inorganic material, such as a metal oxide or a metal nitride, an organic material, such as an insulating organic polymer, or the like.

Source and drain electrodes 14a and 14b are respectively formed on the insulating layer 13. The source and drain electrodes 14a and 14b may overlap predetermined portions of the gate electrode 12 as illustrated in FIG. 1, but the structure of the source and drain electrodes 14a and 14b is not limited thereto. In consideration of the work function of the material that forms an organic semiconductor layer 15, the source and drain electrodes 14a and 14b may be made of a noble metal and the like which has a work function greater than about 5.0 eV. Such a material for forming the source and drain electrodes 14a and 14b may be, but is not limited to, Au, Pd, Pt, Ni, Rh, Ru, Ir, Os, or an alloy of these, preferably, Au, Pd, Pt, Ni, or the like.

The organic semiconductor layer 15 can be entirely formed on the source and the drain electrodes 14a and 14b. An organic semiconductor material that forms the organic semiconductor layer 15 may be pentacene, tetracene, anthracene, naphthalene, α-6-thiophene, α-4-thiophene, perylene and derivatives thereof, rubrene and derivatives thereof, coronene and derivatives thereof, perylene tetracarboxylic diimide and derivatives thereof, perylene tetracarboxylic dianhydride and derivatives thereof, polythiophene and derivatives thereof, polyparaphenylenevinylene and derivatives thereof, polyparaphenylene and derivatives thereof, polyfluorene and derivatives thereof, polythiophene vinylene and derivatives thereof, polythiophene-heteroaromatic copolymer and derivatives thereof, olignaphthalene and derivatives thereof, oligothiophene of α-5-thiophene and derivatives thereof, metal-containing or metal-free phthalocyanine and derivatives thereof, pyromellitic dianhydride and derivatives thereof, pyromellitic diimide and derivatives thereof, or the like, but is not limited thereto.

A channel formation-promoting layer 17 is formed on the organic semiconductor layer 15. The channel formation-promoting layer 17 contacts an opposite region of a channel region of the organic semiconductor layer 15 which is formed when a gate electrode 12 of the TFT of FIG. 3 is supplied with a voltage.

When holes of the organic semiconductor layer 15 move toward the gate electrode 12 to form the channel region and electrons move toward the opposite region of the channel region of the organic semiconductor layer 15 when the gate electrode 12 is supplied with a voltage, the channel formation-promoting layer 17 having an electron-acceptor group-containing compound is used.

The compound containing an electron-acceptor group may be an aromatic compound containing at least one group selected from —NO₂, —CN, —C(═O)—, —COO—, —C(═O)—O—C(═O)—, —CONH—, —SO—, —SO₂—, —C(═O)—C(═O)—, ═N—, —F, —Cl, —I, a C₁₋₁₀ haloalkyl group, and a C₅₋₁₀ haloaryl group.

The C₁₋₁₀ haloalkyl group can be a C₁₋₁₀ alkyl group in which at least one hydrogen is substituted with halogen. The alkyl group may be, for example, a methyl group, an ethyl group, an n-propyl group, an i-propyl group, a butyl group, a pentyl group, a hexyl group, or the like. Among these, a C₁₋₅ haloalkyl group is preferred.

The C₅₋₁₀ haloaryl group may be a C₅₋₁₀ aryl group in which at least one hydrogen is substituted with halogen. The aryl group, which is a radical induced from an aromatic system, may be a phenyl group, a naphthyl group, or the like.

The aromatic compound refers to an unsaturated carbocyclic compound and an unsaturated heterocyclic compound. The aromatic compound contains at least one electron-acceptor group as described above, and at least one compound selected from 5-membered, 6-membered, and 7-membered carbocyclic rings and heterocyclic rings. The carbocyclic rings or heterocyclic rings can be fused to each other, connected by a single bond or an ethenylene group, or coordinated with a metal atom ion, such as an Al ion. The heterocyclic ring refers to a carbocyclic ring in which at least one carbon atom forming the ring is substituted with at least one atom selected from N, S, P, and O.

The aromatic compound contains the electron-acceptor group as described above, and the electron-acceptor group can substitute at least one hydrogen of the aromatic compound or C, N, S, P, or O which forms the ring of the aromatic compound. In addition, a heteroatom of a heterocyclic ring of the aromatic compound may act as the electron-acceptor group.

The aromatic compound containing the electron-acceptor group may be a fluorene-based compound, an aniline-based compound, a benzene-based compound, a naphthalene-based compound, a biphenyl-based compound, a stilbene-based compound, an anthracene-based compound, a dianhydride-based compound, an anhydride-based compound, an imide-based compound, a phenazine-based compound, a quinoxaline-based compound, or the like, which includes at least one electron-acceptor group.

The compound containing the electron-acceptor group may be, but is not limited to, 2,4,7-trinitrofluorenone, 4-nitroaniline, 2,4-dinitroaniline, 5-nitroanthranilonitrile, 2,4-dinitrodiphenylamine, 1,5-dinitronaphthalene, 4-nitrobiphenyl, 4-dimethylamino-4′-nitrostilbene, 1,4-dicyanobenzene, 9,10-dicyanoanthracene, 1,2,4,5-tetracyanobenzene, 3,5-dinitrobenzonitrile, 3,4,9,10-perylenetetracarboxylic dianhydride, N,N′-bis(di-t-butylphenyl)-3,4,9,10-perylenedicarboxyimide), tetrachlorophthalic anhydride, tetrachlorophthalonitrile, tetrafluoro-1,4-benzoquinone, naphthoquinone, anthraquinone, phenanthrenequinone, 1,10-phenanthroline-5,6-dione, phenazine, quinoxaline, 2,3,6,7-tetrachloroquinoxaline, tris-8-hydroxyquinoline aluminum (Alq3), or the like.

When electrons of the organic semiconductor layer 15 move toward the gate electrode 12 to form the channel region and holes move toward the opposite region of the channel region of the organic semiconductor layer 15 when the gate electrode 12 is supplied with a voltage, the channel formation-promoting layer 17 containing the compound containing an electron-donor group can be used.

The compound containing the electron-donor group may be an aromatic compound or a vinyl-based compound containing at least one group selected from hydrogen, a C₁₋₁₀ alkyl group, a C₅₋₁₀ aryl group, a —NR₁R₂ group, a —OR₃ group, and a —SiR₄R₅R₆ group where R₁, R₂, R₃, R₄, R₅ and R₆ are each independently selected from hydrogen, a C₁₋₁₀ alkyl group and a C₅₋₁₀ aryl group.

The C₁₋₁₀ alkyl group is an alkyl group having one to ten carbons. The alkyl group may be, for example, a methyl group, an ethyl group, an n-propyl group, i-propyl group, butyl group, pentyl group, a hexyl group, or the like. Among these, a C₁₋₅ alkyl group is preferred.

The C₅₋₁₀ aryl group is a radical induced from a C₅₋₁₀ aromatic system, and may be phenyl group, a naphthyl group, or the like.

The aromatic compound refers to both an unsaturated carbocyclic compound and an unsaturated heterocyclic compound. The aromatic compound contains at least one electron-donor group as described above, and at least one compound selected from 5-membered, 6-membered, and 7-membered carbocyclic rings and heterocyclic rings. The carbocyclic rings or the heterocyclic rings can be fused to each other, or connected by a single bond or a double bond. The heterocyclic ring refers to a carbocyclic ring in which at least one carbon atom forming the ring is substituted with at least one atom selected from N, S, P, and O. Meanwhile, the vinyl-based compound refers to a compound containing a vinyl group.

The aromatic compound containing the electron-donor group may be a thiophene-based compound, an ethylene-based compound, an azulene-based compound, a pentadiene-based compound, a fulvalene-based compound, or the like which contains at least one electron-donor group as described above.

The compound containing an electron-donor group may be, but is not limited to, poly(3,4-ethylenedioxythiophene), tetraphenylethylene, azulene, 1,2,3,4-tetraphenyl-1,3-cyclopentadiene, bis(ethylenedithio)tetrathiafulvalene, or the like.

As described above, a material for forming the channel formation-promoting layer 17 may be selected according to whether the organic semiconductor layer 15 is a P-type organic semiconductor layer or an N-type organic semiconductor layer, and withdraws electric charges (electrons or holes), which move toward an opposite region of the channel region of the organic semiconductor layer 15, to the interface between the organic semiconductor layer 15 and the channel formation-promoting layer 17. As a result, the channel of the organic semiconductor layer 15 can be easily formed, and thus, a threshold voltage is decreased and electric charge mobility is improved. The material for the channel formation-promoting layer 17 can be any material that can satisfy the mechanism illustrated in FIG. 1 and FIG. 2. In the following case, the description of a material for forming a channel formation-promoting layer is the same as described above.

FIG. 4 is a sectional view of a TFT according to another embodiment. Referring to FIG. 4, a gate electrode 12 with a predetermined pattern is formed on a substrate 11, and an insulating layer 13 covers the gate electrode 12. An organic semiconductor layer 15 is formed on the insulating layer 13, and source and drain electrodes 14a and 14b are formed in predetermined positions corresponding to the gate electrode 12 on the organic semiconductor layer 15.

A channel formation-promoting layer 17 is formed on the source and drain electrodes 14a and 14b, and contacts an opposite region of a channel region of the organic semiconductor layer 15. The channel formation-promoting layer 17 may be made of a compound containing an electron-acceptor group or an electron-donor group such that electric charges (electrons or holes) moving toward the opposite region of the channel region are withdrawn to the interface between the organic semiconductor layer 15 and the channel formation-promoting layer 17. As a result, the formation of the channel region in the organic semiconductor layer 15 is promoted.

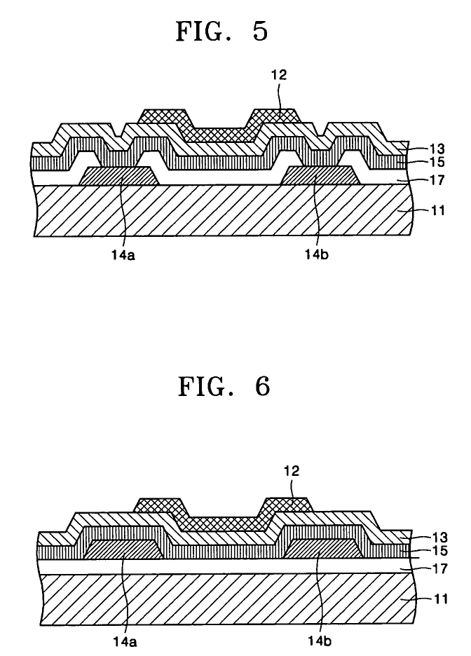

FIG. 5 is a sectional view of a TFT according to yet another embodiment of the present embodiments. Referring to FIG. 5, source and drain electrodes 14a and 14b with a predetermined pattern are formed on a substrate 11. A channel formation-promoting layer 17 is formed on the source and drain electrodes 14a and 14b, and an organic semiconductor layer 15 is formed on the channel formation-promoting layer 17.

The channel formation-promoting layer 17 contacts an opposite region of the channel region of the organic semiconductor layer 15. The channel formation-promoting layer 17 may be made of a compound containing an electron-acceptor group or an electron-donor group such that electric charges (electrons or holes) moving toward the opposite region of the channel region of the organic semiconductor layer 15 are withdrawn to the interface between the organic semiconductor layer 15 and the channel formation-forming layer 17. As a result, the formation of the channel region in the organic semiconductor layer 15 can be promoted.

The channel formation-promoting layer 17 may be formed in a predetermined pattern such that the organic semiconductor layer 15 directly contacts the source and drain electrodes 14a and 14b as illustrated in FIG. 5. The pattern of the channel formation-promoting layer 17 can be different from the pattern illustrated in FIG. 5.

An insulating layer 13 covers the organic semiconductor layer 15, and a gate electrode 12 is formed on the insulating layer 13 such that the gate electrode 12 corresponds to the source and drain electrodes 14a and 14b.

FIG. 6 is a sectional view of a TFT according to still another embodiment. Referring to FIG. 6, a channel formation-promoting layer 17 is formed on a substrate 11, and source and drain electrodes 14a and 14b with a predetermined pattern are formed thereon. An organic semiconductor layer 15 is formed on the source and drain electrodes 14a and 14b.

The channel formation-promoting layer 17 contacts an opposite region of a channel region of the organic semiconductor layer 15. The channel formation-promoting layer 17 may be made of a compound containing an electron-acceptor group or an electron-donor group such that electric charges (electrons or holes) moving toward the opposite region of the channel region of the organic semiconductor layer 15 are withdrawn to the interface between the organic semiconductor layer 15 and the channel formation-forming layer 17. As a result, the formation of the channel region in the organic semiconductor layer 15 can be promoted.

An insulating layer 13 covers the organic semiconductor layer 15, and a gate electrode 12 is formed on the insulating layer 13 such that the gate electrode 12 corresponds to the source and drain electrodes 14a and 14b.

TFTs according to some embodiments are described with reference to FIGS. 3 through 6. However, these TFTs are merely examples, and other various structures can be used in the present embodiments.

Also described is a method of manufacturing a TFT according to an embodiment including forming an insulating layer to cover a gate electrode formed on a substrate; forming source and drain electrodes in predetermined positions on the insulating layer; forming an organic semiconductor layer on the source and drain electrodes; and forming a channel formation-promoting layer contacting an opposite region of a channel region of the organic semiconductor layer.

Respective layers of the TFT can be manufactured using various methods, such as deposition or coating, according to a material for forming a layer.

A method of manufacturing a TFT according to another embodiment of the present embodiments include: forming an insulating layer to cover a gate electrode formed on a substrate; forming an organic semiconductor layer on the insulating layer; forming source and drain electrodes in predetermined positions corresponding to the gate electrode on the organic semiconductor layer; and forming a channel formation-promoting layer contacting an opposite region of a channel region of the organic semiconductor layer.

A method of manufacturing a TFT according to yet another embodiment includes forming a channel formation-promoting layer on source and drain electrodes on a substrate; forming an organic layer on the channel formation-promoting layer; forming an insulating layer covering the organic semiconductor layer; and forming a gate electrode in a predetermined position corresponding to the source and drain electrodes on the insulating layer.

The method may further include forming the channel formation-promoting layer in a pattern such that the source and drain electrodes directly contact the organic semiconductor layer.

A method of manufacturing a TFT according to still another embodiment includes forming a channel formation-promoting layer on a substrate; forming source and drain electrodes on the channel formation-promoting layer; forming an organic semiconductor layer on the source and drain electrodes; forming an insulating layer covering the organic semiconductor layer; and forming a gate electrode in a predetermined position corresponding to the source and drain electrodes on the insulating layer.

The methods of manufacturing a TFT as described above may vary according to the structure of a TFT to be manufactured.

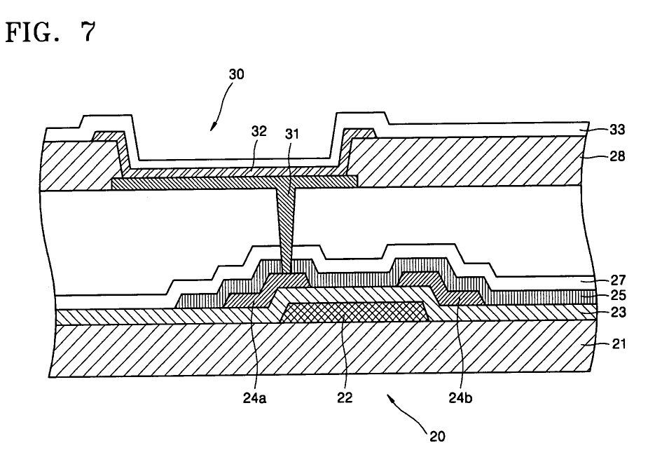

TFTs having structures described above can be used in a flat panel display device, such as LCD or an organic light emitting display device. FIG. 7 is a sectional view of an organic light emitting display device including a TFT as shown in FIG. 3 according to an embodiment.

FIG. 7 illustrates a view of a single sub-pixel of an organic light emitting device. Each sub-pixel includes an organic light emitting device (OLED), which is a self-emissive device, and at least one TFT. The OLED has various pixel patterns according to emission color, preferably, red, green, and blue pixels.

Referring to FIG. 7, a gate electrode 22 with a predetermined pattern is formed on a substrate 21, and an insulating layer 23 covers the gate electrode 22. Source and drain electrodes 24a and 24b are respectively formed on the insulating layer 23, and an organic semiconductor layer 25 is formed on the source and drain electrodes 24a and 24b. A channel formation-promoting layer 27 as described above is formed on the organic semiconductor layer 25. The channel formation-promoting layer 27 withdraws electric charges (electrons or holes), which move toward an opposite region of a channel region of the organic semiconductor layer 25 when the gate electrode 22 is provided with a voltage, to an interface between the channel formation-promoting layer 27 and the organic semiconductor layer 25. Description concerning such TFT 20 has been described above.

A protecting layer and/or a planarization layer is formed on the channel formation-promoting layer 27 to cover a TFT 20. The protecting layer and/or the planarization layer may be a single layer or a multilayer, and may be made of an organic material, an inorganic material, or a complex of an organic material and an inorganic material.

An organic emissive layer 32 of an OLED 30 is formed along a pixel definition layer 28 on the protecting layer and/or the planarization layer.

The OLED 30 emits red, green, and blue light according to the flow of the current, thus forming a predetermined image. The OLED 30 includes a pixel electrode 31 connected to one of the source and drain electrodes 24a and 24b of the TFT 20, a counter electrode 33 covering the entire pixel, and the organic emissive layer 32 that is interposed between the pixel electrode 31 and the counter electrode 33 and emits light. The present embodiments are not necessarily limited to the above structure, and various structures of an organic light emitting device can be used.

The organic emissive layer 32 may be a small molecule organic layer or a polymer organic layer. When the organic emissive layer 32 is a small molecule organic layer, the organic emissive layer 32 may be a hole injection layer (HIL), a hole transport layer (HTL), an emissive layer (EML), an electron transport layer (ETL), an electron injection layer (EIL), or a combination of these. The small molecule organic layer may be copper phthalocyanine (CuPc), N,N′-Di(naphthalene-1-yl)-N,N′-diphenyl-benzidine (NPB), tris-8-hydroxyquinoline aluminum (Alq3), or the like. The small molecule organic layer can be formed using, for example, vacuum deposition.

When the organic emissive layer 32 is a polymer organic layer, the organic emissive layer 32 includes the HTL, and the EML. The HTL may be made of poly-3,4-ethylenedioxythiophene (PEDOT), and the EML may be made of a polyparaphenylenevinylene (PPV)-based or a polyfluorene-based polymer material by screen printing or inkjet printing.

The organic layer 32 is not necessarily limited to the above, and various other structures can be used in the present embodiments.

The pixel electrode 31 may act as an anode, and the counter electrode 33 may act as a cathode. Alternatively, the pixel electrode 31 may act as a cathode, and the counter electrode 33 may act as an anode.

In LCDs, a lower alignment layer covering the pixel electrode 31 is formed, thus completely forming a lower substrate of the LCD.

The TFT according to an embodiment can be installed in respective sub-pixels as shown in FIG. 7, or in a driver circuit (not shown), which does not form an image.

The present embodiments will be described in further detail with reference to the following examples. These examples are for illustrative purposes only and are not intended to limit the scope of the present embodiments.

### EXAMPLE 1

Au was deposited on a substrate of a silicon oxide to a thickness of 1000 Å, thus forming an Au gate electrode with a predetermined pattern. SiO₂ was deposited on the Au gate electrode to a thickness of 1500 Å to form an insulating layer. Then, Au was deposited to a thickness of 1000 Å to form an Au source electrode and an Au drain electrode, and a pentacene layer was formed on the Au source and drain electrodes to a thickness of a 700 Å to form a pentacene organic semiconductor layer. Then, Alq3 was deposited on the organic semiconductor layer to a thickness of 300 Å to form a channel formation-promoting layer containing an electron-acceptor group. As a result, an organic TFT according to the present embodiments was manufactured. This organic TFT will be referred to as Sample 1.

### COMPARATIVE EXAMPLE

An organic TFT was manufactured in the same manner as in Example 1, except that the channel formation-promoting layer made of Alq3 on the organic semiconductor layer was not formed. This organic TFT will be referred to as Sample A.

### Measurement Example—Electric Charge Mobility and On/Off Current Characteristics

Electric charge mobility and on/off current characteristics of Samples 1 and A were measured using a semiconductor parameter analyzer (HP4156C) (Palo Alto, Calif.). The electric charge mobility was measured using Id^{1/2} floating with respect to excessively saturated Vg when Vds is −5V. Meanwhile, the conditions for measuring on/off current characteristics were as follows: drain voltage (Vd)=−5 V and −60 V, gate voltage ranging from 20 V (off) to −60 V (on), and a gate voltage change rate =1 V.

As a result, the electric charge mobility of Sample A was 0.66 cm²/Vs, but the electric charge mobility of Sample 1 was 1.14 cm²/Vs, i.e., nearly double that of Sample A. Thus, it was identified that the electric charge mobility of the organic TFT according to an embodiment was increased.

The on current of Sample A was 1.22×10³A/A, but the on current of Sample 1 was 2.15×10⁵A/A, i.e., roughly 100 times that of Sample A.

Thus, the organic TFT according to the present embodiments has excellent electric charge mobility and on/off current characteristics.

As described above, a TFT according to the present embodiments includes a channel formation-promoting layer to assist the formation of a channel region of an organic semiconductor layer. Thus, a TFT with a decreased threshold voltage, an improved electric charge mobility, and improved on-current characteristics can be obtained. Further, a flat panel display device including the TFT is very reliable.

While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. A thin film transistor comprising:
a gate electrode;
source and drain electrodes insulated from the gate electrode;
an organic semiconductor layer that is insulated from the gate electrode and electrically connected to the source and drain electrodes;
an insulating layer that insulates the gate electrode from the source and drain electrodes or the organic semiconductor layer; and
a channel formation-promoting layer that contacts an opposite region of a channel region of the organic semiconductor layer, and contains a compound having a functional group, which fixes electric charges moving toward the opposite region of the channel region to the opposite region of the channel region.

2. The thin film transistor of claim 1, wherein when holes move toward the channel region and electrons move toward the opposite region of the channel region, and wherein the channel formation-promoting layer comprises a compound comprising an electron-acceptor group.

3. The thin film transistor of claim 2, wherein the compound containing the electron-acceptor group may be an aromatic compound having at least one group selected from the group consisting of —NO₂, —CN, —C(═O)—, —COO—, —C(═O)—O—C(═O)—, —CONH—, —SO—, —SO₂—, —C(═O)—C(═O)—, ═N—, —F, —Cl, —I, C₁₋₁₀ haloalkyl group, and C₅₋₁₀ haloaryl group.

4. The thin film transistor of claim 3, wherein the aromatic compound comprises at least one compound selected from 5-membered, 6-membered, and 7-membered carbocyclic rings and heterocyclic rings, wherein the carbocyclic rings or the heterocyclic rings are fused to each other, connected by a single bond or an ethenylene group, or coordinated with a metal atom.

5. The thin film transistor of claim 2, wherein the compound having the electron-acceptor group contains at least one compound selected from the group consisting of 2,4,7-trinitrofluorenone, 4-nitroaniline, 2,4-dinitroaniline, 5-nitroanthranilonitrile, 2,4-dinitrodiphenylamine, 1,5-dinitronaphthalene, 4-nitrobiphenyl, 4-dimethylamino-4′-nitrostilbene, 1,4-dicyanobenzene, 9,10-dicyanoanthracene, 1,2,4,5-tetracyanobenzene, 3,5-dinitrobenzonitrile, 3,4,9,10-perylenetetracarboxylic dianhydride, N,N′-bis(di-t-butylphenyl)-3,4,9,10-perylenedicarboxyimide), tetrachlorophthalic anhydride, tetrachlorophthalonitrile, tetrafluoro-1,4-benzoquinone, naphthoquinone, anthraquinone, phenanthrenequinone, 1,10-phenanthroline-5,6-dione, phenazine, quinoxaline, 2,3,6,7-tetrachloroquinoxaline, and tris-8-hydroxyquinoline aluminum (Alq3).

6. The thin film transistor of claim 1, wherein electrons move toward the channel region and holes move toward the opposite region of the channel region, and wherein the channel formation-promoting layer comprises a compound comprising an electron-donor group.

7. The thin film transistor of claim 6, wherein the compound having the electron-donor group is an aromatic compound or a vinyl-based compound containing at least one group selected from the group consisting of hydrogen, a C₁₋₁₀ alkyl group, a C₅₋₁₀ aryl group, a —NR₁R₂ group, a —OR₃ group, and a —SiR₄R₅R₆ group wherein R₁, R₂, R₃, R₄, R₅ and R₆ are each independently selected from hydrogen, a C₁₋₁₀ alkyl group and a C₅₋₁₀ aryl group.

8. The thin film transistor of claim 7, wherein the aromatic compound comprises at least one compound selected from 5-membered, 6-membered, and 7-membered carbocyclic rings and heterocyclic rings, and wherein the carbocyclic rings or the heterocyclic rings are fused to each other, or connected by a single bond or a double bond.

9. The thin film transistor of claim 6, wherein the compound containing the electron-donor group contains at least one compound selected from the group consisting of poly(3,4-ethylenedioxythiophene), tetraphenylethylene, azulene, 1,2,3,4-tetraphenyl-1,3-cyclopentadiene, and bis(ethylenedithio)tetrathiafulvalene.

10. The thin film transistor of claim 1, wherein the gate electrode, the insulating layer, the source and drain electrodes, the organic semiconductor layer, and the channel formation-promoting layer are sequentially formed.

11. The thin film transistor of claim 1, wherein the gate electrode, the insulating layer, the organic semiconductor layer, the source and drain electrodes, and the channel formation-promoting layer are sequentially formed.

12. The thin film transistor of claim 1, wherein the source and drain electrodes, the channel formation-promoting layer, the organic semiconductor layer, the insulating layer, and the gate electrode are sequentially formed.

13. The thin film transistor of claim 12, wherein the channel formation-promoting layer is formed in a predetermined pattern such that the source and drain electrodes directly contact the organic semiconductor layer.

14. The thin film transistor of claim 1, wherein the channel formation-promoting layer, the source and drain electrodes, the organic semiconductor layer, the insulating layer, and the gate electrode are sequentially formed.

15. A method of manufacturing a thin film transistor, the method comprising:
forming a gate electrode on a substrate;
forming an insulating layer to cover the gate electrode formed on the substrate;
forming source and drain electrodes in predetermined positions corresponding to both ends of the gate electrode on the insulating layer;
forming an organic semiconductor layer on the source and drain electrodes; and
forming a channel formation-promoting layer contacting an opposite region of a channel region of the organic semiconductor layer.

16. A method of manufacturing a thin film transistor, the method comprising:
forming a gate electrode on a substrate;
forming an insulating layer to cover the gate electrode formed on the substrate;
forming an organic semiconductor layer on the insulating layer;
forming source and drain electrodes in predetermined positions corresponding the gate electrode on the organic semiconductor layer; and
forming a channel formation-promoting layer contacting an opposite region of a channel region of the organic semiconductor layer.

17. A method of manufacturing a thin film transistor, the method comprising:
forming souce and drain electrodes on a substrate;
forming a channel formation-promoting layer on the source and drain electrodes formed on the substrate;
forming an organic semiconductor layer on the channel formation-promoting layer;
forming an insulating layer covering the organic semiconductor layer; and
forming a gate electrode in a predetermined position corresponding to the source and drain electrodes on the insulating layer.

18. A method of manufacturing a thin film transistor, the method comprising:
forming a channel formation-promoting layer on a substrate;
forming source and drain electrodes on the channel formation-promoting layer;
forming an organic semiconductor layer on the source and drain electrodes; and
forming an insulating layer covering the organic semiconductor layer; and
forming a gate electrode in a predetermined position corresponding to the source and drain electrodes on the insulating layer.

19. A flat panel display device comprising the thin film transistor of claim 1, wherein the source electrode or the drain electrode of the thin film transistor is connected to a pixel electrode.
